(19) United States
(12) Patent Application Publication
(10) Pub. No.: US 2014/0036633 A1
(43) Pub. Date: Feb. 6, 2014

(54) ULTRASONIC PROBE

(71) Applicant: York Oberdoerfer, Langenfeld (DE)

(72) Inventor: York Oberdoerfer, Langenfeld (DE)

(73) Assignee: General Electric Company, Schenectady, NY (US)

(21) Appl. No.: 13/563,054

(22) Filed: Jul. 31, 2012

(51) Int. Cl. B06B 1/06; H01L 41/053

(52) U.S. Cl. 367/140; 310/336

(57) ABSTRACT

An array of ultrasonic transducers is formed on a piezoelectric polymer foil. Ultrasonic transducer electrodes are formed on a first side of the foil and a ground layer is formed on a second side of the foil.

### BACKGROUND OF THE INVENTION

The subject matter disclosed herein relates to an ultrasonic probe and, in particular, to a probe operable at high ultrasonic frequencies.

Nondestructive testing devices can be used to inspect test objects to detect and analyze anomalies in the objects. Nondestructive testing allows an inspection technician to maneuver a probe near the surface of the test object in order to perform testing of both the object surface and its underlying structure. One example of nondestructive testing is ultrasonic testing.

In an ultrasonic testing system, electrical pulses are transmitted to an ultrasonic probe where they are transformed into ultrasonic pulses by one or more ultrasonic transducers (e.g., piezoelectric elements) in the ultrasonic probe. During operation, the electrical pulses are applied to the electrodes of one or more ultrasonic transducers, generating ultrasonic waves that are transmitted into the test object to which the probe is coupled. As the ultrasonic waves pass through the test object, various reflections, called echoes, occur as the ultrasonic wave interacts with anomalies in the test object. Conversely, when an ultrasonic wave reflected from the test object contacts the surface of the piezoelectric ceramic of an ultrasonic transducer, it causes the ultrasonic transducers to vibrate, generating a voltage difference across the ultrasonic transducer electrodes that is detected as an electrical signal by signal processing electronics. By tracking the time difference between the transmission of the electrical pulse and the receipt of the electrical signal, and measuring the amplitude of the received electrical signal, various characteristics of the anomaly (e.g., depth, size, orientation) can be determined. A phased array ultrasonic probe has a plurality of electrically and acoustically independent ultrasonic transducers in a single one or two dimensional array.

The frequency of the ultrasonic waves generated by the array of ultrasonic transducers determines the size of the anomalies that are detectable by the ultrasonic probe as well as whether two closely spaced anomalies can be distinguished by the probe. A smaller anomaly, as well as closely spaced anomalies, in the test object requires ultrasonic waves at high frequencies in order to be detected. This, in turn, requires that the piezoelectric surface in an ultrasonic transducer vibrate at higher frequencies. In order to vibrate at extremely high frequencies to detect very small anomalies, a ceramic layer, which is typically rigid, must be manufactured as a very thin layer, which may not be feasible, and so makes the process expensive and the fragile ceramic material difficult to handle. Moreover, small test objects may also require a test apparatus having an array of ultrasonic transducers that is tightly curved. A conventional ultrasonic transducer array made of ceramic material is not capable of being formed in a tight curve.

The discussion above is merely provided for general background information and is not intended to be used as an aid in determining the scope of the claimed subject matter.

### BRIEF DESCRIPTION OF THE INVENTION

An array of ultrasonic transducers formed on a flexible piezoelectric polymer foil is disclosed. Ultrasonic transducer electrodes are formed on a first side of the foil and a ground layer is formed on a second side of the foil. An advantage that may be realized in the practice of some disclosed embodiments of a probe made from such an arrangement of ultrasonic transducers is the clear detection of smaller flaws in test objects than were capable of detection heretofore. The use of a flexible piezoelectric polymer foil means that it can be regulated to emit ultrasonic energy at higher frequencies in order to detect minute flaws. Another advantage that may be realized in the practice of other disclosed embodiments of such ultrasonic transducers is the wider range of probe contours that can be formed in order to accommodate testing of smaller objects. A piezoelectric polymer foil, such as polyvinylidenfluorid (“PVDF”), is sufficiently thin and flexible that it can be made to vibrate at higher ultrasonic frequencies, thereby increasing the resolution obtainable from ultrasonic testing. It is also flexible enough so that it can be attached to a probe structure having corners or other tight curvatures.

In one embodiment, an ultrasonic probe is disclosed comprising a piezoelectric polymer foil having a first side, and a second side opposite the first side. The first side of the foil comprises a ground layer and the second side comprises an array of ultrasonic transducer electrodes. A backing having a predetermined curved shape is used to attach the foil with the second side of the foil facing the backing The foil conforms to the shape of the backing

In another embodiment, an apparatus is disclosed having a curved backing made of dielectric material. A piezoelectric polymer foil is disposed on the backing The foil has a ground layer on the first side of the foil and a plurality of ultrasonic transducer electrodes on the second side of the foil, with the second side facing the backing The ground layer, the ultrasonic transducer electrodes and the foil form an array of ultrasonic transducers.

This brief description of the invention is intended only to provide a brief overview of subject matter disclosed herein according to one or more illustrative embodiments, and does not serve as a guide to interpreting the claims or to define or limit the scope of the invention, which is defined only by the appended claims. This brief description is provided to introduce an illustrative selection of concepts in a simplified form that are further described below in the detailed description. This brief description is not intended to identify key features or essential features of the claimed subject matter, nor is it intended to be used as an aid in determining the scope of the claimed subject matter. The claimed subject matter is not limited to implementations that solve any or all disadvantages noted in the background.

### BRIEF DESCRIPTION OF THE DRAWINGS

So that the manner in which the features of the invention can be understood, a detailed description of the invention may be had by reference to certain embodiments, some of which are illustrated in the accompanying drawings. It is to be noted, however, that the drawings illustrate only certain embodiments of this invention and are therefore not to be considered limiting of its scope, for the scope of the invention encompasses other equally effective embodiments. The drawings are not necessarily to scale, emphasis generally being placed upon illustrating the features of certain embodiments of the invention. In the drawings, like numerals are used to indicate like parts throughout the various views. Thus, for further understanding of the invention, reference can be made to the following detailed description, read in connection with the drawings in which:

FIG. 1 is a diagram of an exemplary high frequency ultrasonic probe for detecting small flaws;

FIG. 2 is a top view of a ultrasonic transducer array formed on a piezoelectric polymer foil;

FIG. 3 is a bottom view of the ultrasonic transducer array of FIG. 2 formed on a piezoelectric polymer foil;

FIG. 4 is cross-section A-A of the high frequency ultrasonic probe shown in FIG. 1; and

FIG. 5 illustrates another exemplary high frequency ultrasonic probe.

### DETAILED DESCRIPTION OF THE INVENTION

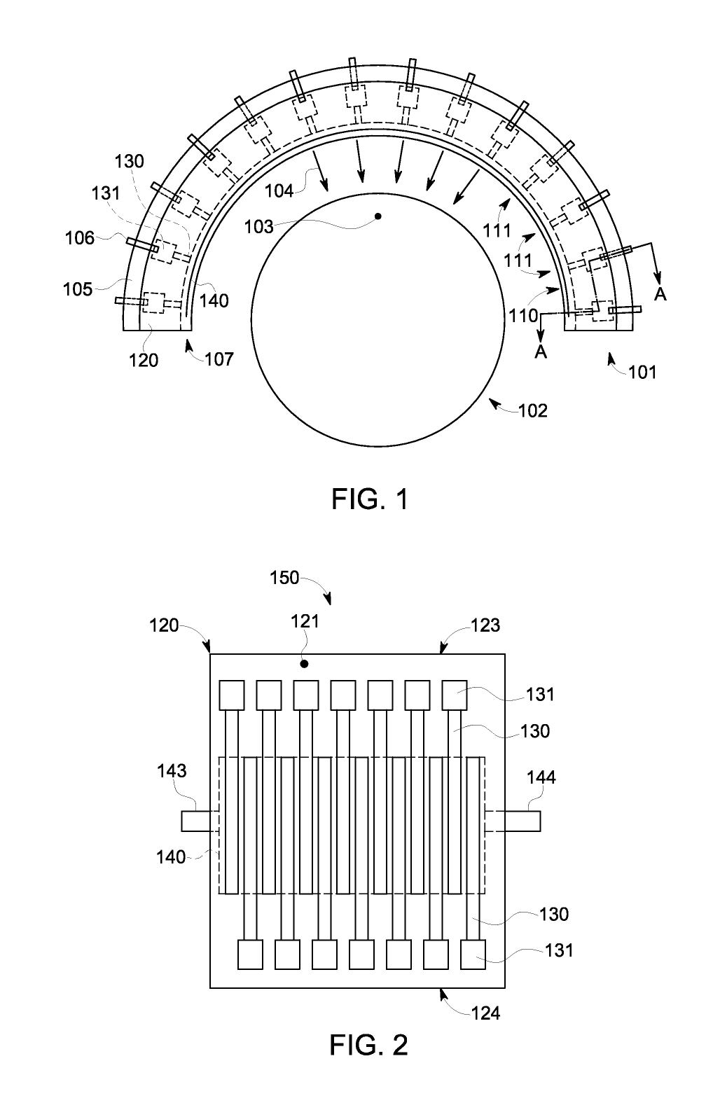

FIG. 1 illustrates a high frequency ultrasonic probe 101 being used to inspect test object 102, which can be, for example, a bar or billet, in order to detect a small flaw 103 in the material of the test object. The ultrasonic probe 101, formed in a predetermined curved shape, or contour, in this embodiment, comprises ultrasonic transducers 111 on an active surface 110 of the ultrasonic probe 101 which direct ultrasonic energy 104 toward the test object 102. A subset of the ultrasonic transducers 111 is typically activated at one time to emit ultrasonic energy 104 toward a test object. A portion of the ultrasonic transducer electrodes 130 extend from the active surface 110 of the ultrasonic probe 101 onto a side surface (the side facing the viewer in FIG. 1) of the ultrasonic probe 101. Another portion of the ultrasonic transducer electrodes 130 extend from the active surface 110 of the ultrasonic probe 101 onto an opposite side surface (the side opposite, and not visible to, the viewer in FIG. 1) of the ultrasonic probe 101. These ultrasonic transducer electrodes 130 terminate at terminal pads 131 which are employed to electrically connect the ultrasonic transducer electrodes 130 to external electronics using electrical signal lines 106 for sending and receiving electrical signals to and from the ultrasonic transducer electrodes 130.

Electrical signals sent to the ultrasonic transducer electrodes 130 cause the piezoelectric polymer foil 120 to vibrate at a high ultrasonic frequency and emit ultrasonic energy 104. Electrical signals are sent from the ultrasonic transducer electrodes 130 when ultrasonic energy 104 impacts the piezoelectric polymer foil 120 causing it to vibrate and generate electrical signals in the ultrasonic transducer electrodes 130. The ultrasonic transducer electrodes 130 are formed on a first side 121 (FIG. 2) of piezoelectric polymer foil 120, described below, which is folded around a backing 105 and attached thereto, with the first side of the piezoelectric polymer foil 120 facing the backing 105. The backing is formed in the shape of an arc and provides the shape for the ultrasonic probe 101, as shown in FIG. 1. The piezoelectric polymer foil 120 conforms to the shape of the backing 105 when it is attached thereto. In one embodiment, the backing is made of a dielectric material such as plexiglass or polystyrene. The predetermined semicircular arc shape allows each of the ultrasonic transducers 111 on the active surface 110 of the ultrasonic probe 101 to be situated at a substantially equal distance from test object 102, i.e. active surface 110 of the ultrasonic probe 101 is substantially parallel to the outer surface of test object 102, when it is attached to the backing 105, so that the ultrasonic energy 104 emitted from each ultrasonic transducer 111 penetrates the test object uniformly, for example, to a uniform depth, during inspection.

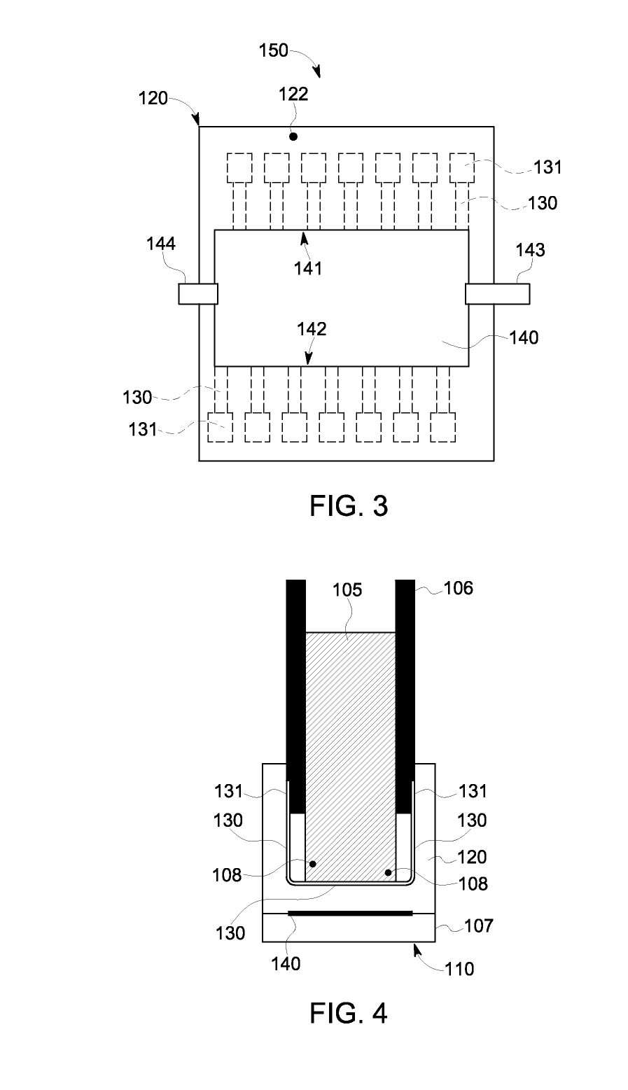

An electrically conductive ground layer 140 is formed on a second side 122 (FIG. 3) of the piezoelectric polymer foil 120 opposite the ultrasonic transducer electrodes 130. When the piezoelectric polymer foil 120 is attached to the backing 105, the first side 121 of piezoelectric polymer foil 120 faces the backing 105 and the second side 122 of piezoelectric polymer foil 120 faces away from the backing 105. Protective tape 107 is placed over the ultrasonic transducers 111. In one embodiment, the protective tape is a polyimide tape.

FIG. 2 illustrates a top view of a one dimensional ultrasonic transducer array 150 formed on the piezoelectric polymer foil 120, which can be made of polyvinylidenfluorid, for example. This example embodiment comprises a one-dimensional ultrasonic transducer array 150, e.g. a single row. However, a separate embodiment comprising multiple rows of ultrasonic transducers arranged in a two-dimensional array are also contemplated in the present patent application. The piezoelectric polymer foil 120 includes a first side 121 and a second side 122 (FIG. 3) opposite the first side 121. The array of ultrasonic transducer electrodes 130 are formed in a region on the first side 121 of piezoelectric polymer foil 120 by sputter deposition or by electrochemical processes, using copper, gold, titanium, or other suitable materials that are conductive and exhibit good adhesion to the piezoelectric polymer foil 120. Terminal pads 131 can be formed integrally with the ultrasonic transducer electrodes 130 and are used for easily electrically connecting the ultrasonic transducer electrodes 130 of the ultrasonic transducer array 150 to external processing electronics using electrical signal lines 106 (FIG. 1). The electrical signal lines 106 can be sputtered onto the piezoelectric polymer foil 120 to electrically contact the terminal pads 131. The terminal pads 131 can also be electrically contacted via wire-bonding, soldering, or other similar techniques. The terminal pads closest to either side edge 123, 124 of the piezoelectric polymer foil 120 are connected in sequence to every other one of the ultrasonic transducer electrodes 130.

FIG. 3 illustrates a bottom view of the one dimensional ultrasonic transducer array 150 formed on piezoelectric polymer foil 120. Ground layer 140 is formed in a region on the second side 122 of piezoelectric polymer foil 120 by sputter deposition or by electrochemical processes, using copper, gold, titanium, or other suitable materials that are conductive and exhibit good adhesion to the piezoelectric polymer foil. The area of the ground layer 140 on the second side of the piezoelectric polymer foil 120 overlies the ultrasonic transducer electrodes 130 of the ultrasonic transducer array 150 on the first side of the piezoelectric polymer foil 120. This overlying region, substantially defined by the area of ground layer 140, is the active region of the ultrasonic transducer array 150. Electrical leads 143, 144 can be formed integrally with ground layer 140 and are electrically connected to opposite ends of the ground layer 140 to provide ground voltage thereto. The ground layer 140, as seen in FIG. 3, faces toward the test object 102, shown in FIG. 1, when the piezoelectric polymer foil 120 is attached to backing 105. The piezoelectric polymer foil 120 is folded substantially along the ground layer 140 side edges 141, 142 when attached to backing 105, as shown in FIG. 1. Thus, the active region of the ultrasonic transducer array 150 substantially covers a width of the active surface 110 of the ultrasonic probe 101.

In one embodiment of the ultrasonic transducer array 150, the width of the ultrasonic transducer electrodes 130 in the active region is about 0.5 mm separated by about 0.2 mm. The ultrasonic transducer electrodes 130 of the ultrasonic transducer array 150 formed at this higher pitch allow higher frequency operation of the ultrasonic probe, for example, at a frequency of about 20 MHz. Also, the foil is sufficiently flexible, at a thickness of about 0.7 mm, to be attached to a small concave radius of curvature formed by backing 105. This geometry allows an ultrasonic probe so formed to be used during inspection of bars, billets, or other test objects 102 having a diameter of 10 mm or less.

FIG. 4 is cross section A-A of the ultrasonic probe 101 of FIG. 1. Piezoelectric polymer foil 120 comprises ultrasonic transducer electrodes 130 and terminal pads 131 formed on the second surface thereof, and ground layer 140 formed on the first surface thereof. The piezoelectric polymer foil 120 is folded around corners 108 of backing 105. Electrical signal lines 106 are in electrical contact with terminal pads 131. A major area of the active surface 110 of the ultrasonic probe 101 comprises the active area of the ultrasonic transducer array 150 as defined by the region comprising ground layer 140. The protective tape 107 is applied to the exposed surface of the ground layer 140 and the piezoelectric polymer foil 120.

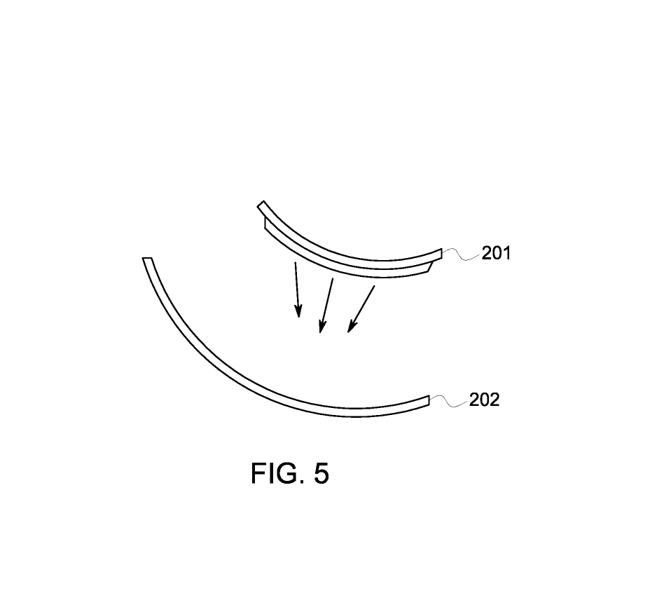

FIG. 5 illustrates another configuration of an ultrasonic probe 201 for testing a curved surface of test object 202. In this embodiment, the ultrasonic transducer array is formed on a piezoelectric polymer foil and is attached to a backing formed in a convex curved shape, using methods as described above, and operates in the same manner as described above.

It is important to note that the example embodiment of FIGS. 1, 2, and 3, shows a certain number of ultrasonic transducers forming the ultrasonic transducer array 150 for purposes of clarity in the figures. A typical arrangement of ultrasonic transducers 111 would include 64, 128, 256, or more individual ultrasonic transducers 111.

In view of the foregoing, embodiments of the invention enable higher frequency operation of an ultrasonic probe and flexible formation of the ultrasonic transducer array 150 into a variety of shapes capable of detecting small flaws in test objects, distinguishing closely spaced flaws, and inspecting test objects of small size.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. An ultrasonic probe comprising:
a piezoelectric polymer foil comprising a first side and a second side opposite the first side;
a region on the first side of the foil comprising a ground layer;
a region on the second side of the foil comprising an array of ultrasonic transducer electrodes; and
a backing comprising a predetermined curved shape,
wherein the foil is attached to the backing, the second side of the foil faces the backing, and wherein the foil conforms to the shape of the backing

2. The ultrasonic probe of claim 1, wherein the array of ultrasonic transducer electrodes and the ground layer are made from copper, titanium, gold, or a combination thereof.

3. The ultrasonic probe of claim 2, wherein the layer of piezoelectric polymer foil is made from polyvinylidenfluorid.

4. The ultrasonic probe of claim 1, further comprising ground lines connected to opposite ends of the ground layer for connecting the ground layer to a voltage ground.

5. The ultrasonic probe of claim 1, further comprising a plurality of electrical signal lines each connected to one ultrasonic transducer electrode of the array of ultrasonic transducer electrodes for transmitting electrical signals to each of the ultrasonic transducer electrodes for causing the piezoelectric polymer foil to emit ultrasonic energy and for transmitting electrical signals from the ultrasonic transducer electrodes when the piezoelectric polymer foil detects ultrasonic energy impacting the probe.

6. The ultrasonic probe of claim 5, wherein the ultrasonic transducer electrodes in the array of ultrasonic transducer electrodes comprise a width of about 0.5 mm separated by about 0.2 mm, a thickness of the foil is about 0.07 mm, and wherein the electrical signals comprise a frequency of about 20 MHz.

7. The ultrasonic probe of claim 1, wherein the dielectric backing comprises a concave curved shape.

8. The ultrasonic probe of claim 1, wherein the dielectric backing comprises a convex curved shape.

9. The ultrasonic probe of claim 1, wherein the predetermined shape of the backing is formed having a radius of curvature of about 10 mm or less.

10. An apparatus comprising:
a curved backing made of dielectric material;
a piezoelectric polymer foil disposed on the backing, the foil having a first side and a second side opposite the first side, the second side facing the backing;
a ground layer on a region of the first side of the foil;
a plurality of ultrasonic transducer electrodes on a region of the second side of the foil; and
wherein the ground layer, the ultrasonic transducer electrodes and the foil form an array of ultrasonic transducers.

11. The apparatus of claim 10, wherein the backing comprises a concave shape having a radius of curvature of about 10 mm or less.

12. The apparatus of claim 10, wherein the array of ultrasonic transducer electrodes and the ground layer comprise copper, titanium, gold, or a combination thereof.

13. The apparatus of claim 10, wherein the piezoelectric polymer foil comprises polyvinylidenfluorid.

14. The apparatus of claim 10, further comprising ground lines connected to opposite ends of the ground layer for connecting the ground layer to a voltage ground.

15. The apparatus of claim 14, further comprising a plurality of electrical signal lines each connected to one of the plurality of ultrasonic transducer electrodes for transmitting electrical signals to each of the ultrasonic transducer electrodes for causing the piezoelectric polymer foil to emit ultrasonic energy and for transmitting electrical signals from the ultrasonic transducer electrodes when the piezoelectric polymer foil detects ultrasonic energy impacting the apparatus.

16. The apparatus of claim 15, wherein the ultrasonic transducer electrodes comprise a width of about 0.5 mm separated by about 0.2 mm, a thickness of the foil is about 0.07 mm, and wherein the electrical signals comprise a frequency of about 20 MHz.

17. The apparatus of claim 10, wherein the dielectric backing comprises a convex curved shape.

18. The apparatus of claim 10, wherein the dielectric backing comprises a concave curved shape.
